(19) United States
(12) Patent Application Publication
(10) Pub. No.: US 2024/0212784 A1
(43) Pub. Date: Jun. 27, 2024

(54) CALIBRATE SYSTEM WITH CALCULATED RECEIVE EYE FOR VOLUME TESTING BASED ON RECEIVE EYE MEASUREMENT IN A DIFFERENT SYSTEM

(71) Applicant: Intel NDTM US LLC, Santa Clara, CA (US)

(72) Inventors: Ashish SHUKLA, San Jose, CA (US); Tri TRAN, Elk Grove, CA (US); Sriram BALASUBRAHMANYAM, Folsom, CA (US); Trung PHAN, Sunnyvale, CA (US)

(21) Appl. No.: 18/600,537

(22) Filed: Mar. 8, 2024

(51) Int. Cl. G11C 29/56

(52) U.S. Cl. CPC G11C 29/56016; G11C 29/56004; G11C 2029/5602

(57) ABSTRACT

A test system for memory can be calibrated based on an indirect determination of the channel loss. A characteristic receive eye parameter can be computed for a memory die on a first test platform, and then used to indirectly determine the channel loss for a different test platform. The different test platform can adjust the transmit data eye based on the calculation of its channel loss.

### TECHNICAL FIELD

Descriptions are generally related to device interconnect, and more particular descriptions are related to training the data eye margin.

### BACKGROUND OF THE INVENTION

A memory subsystem has a DQ (data) bus between the host and the memory devices. Due to channel loss, the data eye for the transmitted signal is larger and cleaner than the data eye for the signal received at the memory device. Specifications define characteristic setup and hold times for a passing eye at the memory device DQ interface. Channel loss refers to the distortions in the waveform due to noise and impedance. The PW (passing window) refers to having a data eye of sufficient size within the space defined by the sequence of data signals sent on the DQ signal lines of the data bus.

Testing the memory can involve sending high-speed signals on a test DQ bus to the memory device. However, for channels that are heavily loaded, having multiple memory dies coupled to the multidrop bus, the receive data eye cannot be directly measured due to reflections impedance introduced by oscilloscope probes. Rather than directly measuring the receive eye, testing can connect capacitors and other loading to simulate the presence of other memory dies connected to the channel.

A heavily loaded channel cannot be reliably measured like a lightly loaded channel, which can result in testing for a heavily loaded channel showing different characteristics than testing for a light loaded channel. A lightly loaded channel can be a channel having a single memory die, and an example of a heavily loaded channel can be a multi-die package. Another example is bench testing of individual dies (lightly loaded) versus volume testing (heavily loaded). Thus, single die testing results and volume testing results can differ significantly. Similarly, testing on a platform where the die can be probed can result in different testing results that are different from a platform where probing is impractical.

### BRIEF DESCRIPTION OF THE DRAWINGS

The following description includes discussion of figures having illustrations given by way of example of an implementation. The drawings should be understood by way of example, and not by way of limitation. As used herein, references to one or more examples are to be understood as describing a particular feature, structure, or characteristic included in at least one implementation of the invention. Phrases such as “in one example” or “in an alternative example” appearing herein provide examples of implementations of the invention, and do not necessarily all refer to the same implementation. However, they are also not necessarily mutually exclusive.

FIG. 1A is a block diagram of an example of a system that trains I/O for a memory die and can measure receive eye characteristics.

FIG. 1B is a block diagram of an example of a system that trains I/O for multiple memory dies based on a characteristic receive eye parameter for the memory dies.

FIG. 2 is a diagrammatic example of a receive data eye in response to a transmit data eye.

FIG. 3 is a flow diagram of an example of a process for measuring a characteristic receive eye parameter for a memory die.

FIG. 4 is a flow diagram of an example of a process for calibrating a system based on a characteristic receive eye parameter for a memory die.

FIG. 5 is a block diagram of an example of a memory subsystem in which I/O training can be implemented.

FIG. 6 is a block diagram of an example of a computing system in which I/O training can be implemented.

Descriptions of certain details and implementations follow, including non-limiting descriptions of the figures, which may depict some or all examples, and well as other potential implementations.

### DETAILED DESCRIPTION OF THE INVENTION

As described herein, a test system for HSIO (high speed input/output) can be calibrated based on an indirect determination of the channel loss based on a characteristic receive eye parameter for the device under test. The descriptions herein apply to testing any HSIO channel. For simplicity, the descriptions below primarily provide examples of testing memory data IO. It will be understood that the descriptions can apply to other IO channels.

At high speeds, the transmitted eye driven by a tester is larger than the received eye at the receiver IO hardware, such as a package ball or pin, due to channel losses (CL). The tester for a HSIO test provides an input signal with a known width and height, which can be referred to as the transmitted eye (T) (alternatively, the transmit eye or TX eye). The receiver device sees a smaller eye, which can be referred to as the received eye (R) (alternatively, the receive eye or RX eye).

The channel losses are hard to quantify, especially in a heavily loaded channel. It can be impracticable or nearly impossible to accurately characterize the received eye by visual inspection for a heavily loaded channel due to reflections and impedance of measurement equipment. Low loss channels may be relatively easy to measure if the RX eye can be probed using measurement devices such as an oscilloscope or other techniques such as using a dummy socket.

Channel loss can be determined based on characteristic receive eye parameters computed for a semiconductor die (e.g., a memory die) on a first test platform using measurement. The measurement on the first test platform can be used to characterize parameters for an entire batch of semiconductor dies, seeing that the batch tends to have the same characteristics. The computed characteristics for the semiconductor die in the first test platform can then be used for semiconductor dies in a volume test platform to indirectly determine the channel loss for the different test platform. The volume test platform can determine the receive eye based on the computed characteristics. The different test platform can be calibrated and adjust the transmit data eye based on the calculation of its channel loss based on characteristic receive eye parameters.

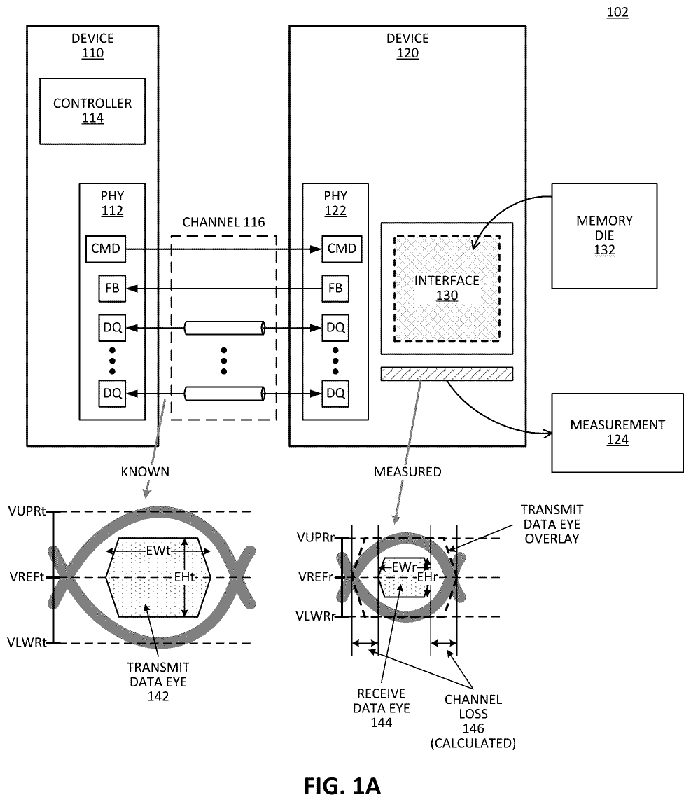

FIG. 1A is a block diagram of an example of a system that trains I/O for a memory die and can measure receive eye characteristics. System 102 includes two devices coupled over a communication channel. System 102 represents a system with two devices that communicate over an HSIO channel. Channel 116 represents the high-speed channel. In one example, system 102 is an example of a memory subsystem, with device 110 as the host/memory controller, and device 120 as the memory device. The memory device can be a DRAM (dynamic random access memory) device, a NAND memory device, or other memory device.

Device 110 includes PHY (physical interface) 112 and device 120 includes PHY (physical interface) 122. PHY 112 and PHY 122 include DQ (data) signal line interfaces, coupled together through signal lines. The number of DQ interfaces depends on the data bus for the system used, such as 4 signal lines, 8 signal lines, 10 signal lines, or some other number of data signal lines in the data bus.

PHY 112 and PHY 122 also illustrate CMD (command) signal line interfaces, and FB (feedback) signal line interfaces. The command is typically multiple signal lines, and is a unidirectional bus from the sender to the receiver. The feedback line can be one or more signal lines for the receiver to provide feedback to the sender. In one example, the receiver provides feedback over the data bus. PHY 112 includes transmitter circuitry for the CMD bus, receiver circuitry for the feedback signal, and transceiver circuitry for the data bus. PHY 122 includes receiver circuitry for the CMD bus, transmitter circuitry for the feedback signal, and transceiver circuitry for the data bus.

Device 110 includes controller 114, which represents control logic for device 110. Controller 114 includes hardware logic to control PHY 112. Controller 114 can execute firmware to manage PHY 112. Controller 114 can manage the voltage levels for the transmit signals that make up the transmit data eye. Device 120 will also have a controller to manage PHY 122, which is not specifically illustrated in system 102.

Transmit data eye 142 represents the data eye transmitted from the DQ interfaces from PHY 112. Transmit data eye 142 has known EWt (transmit eye width) and known EHt (transmit eye height). The transmit data eye is defined by the area enclosed within the vertical limits of VUPRt (transmit upper voltage) and VLWRt (transmit lower voltage) and horizontally as complementary signals cross VREFt (transmit reference voltage). The dark lines represent averages of transmitted signals, with signals rising to VUPRt being asserted bits (a logic one) and signals going to VLWRt being de-asserted bits (a logic zero).

After transmission on channel 116, the data eye will shrink due to channel loss. The representation in system 102 is not necessarily representative of a real signal, but illustrates a smaller receive data eye 144. With device 110 as the tester, the bits it sends on the DQ bus to device 120 are clean waveforms. Regardless of what is shown in system 102, the waveform for what is measured at the waveform is not necessarily as clean as the transmit signals.

Receive data eye 144 has EWr (receive eye width) and EHr (receive eye height). The receive data eye is defined by the area enclosed within the vertical limits of VUPRr (receive upper voltage) and VLWRr (receive lower voltage) and horizontally as complementary signals cross VREFr (receive reference voltage).

System 102 illustrates a dashed outline of transmit data eye 142 over receive data eye 144, labeled as “transmit data eye overlay”. The diagram illustrates the difference in setup and hold times between receive data eye 144 and transmit data eye 142 as channel loss 146. While the setup and hold time differences between the transmit eye and the receive eye are illustrated as being relatively the same, in one example, the setup time is longer than the hold time. In one example, the setup time is shorter than the hold time. Channel loss 146 can be calculated based on the measurement of receive data eye 144 and the known parameters of transmit data eye 142.

System 102 illustrates interface 130 to receive memory die 132. Memory die 132 represents a silicon die to test for IO. PHY 122 is illustrated within device 120, and it will be understood that the physical interface is located within memory die 132 to be tested. In one example, device 120 represents a portion of a test system that enables direct measurement of the DQ signals for memory die 132. Measurement 124 represents measurement equipment, such as an oscilloscope or other hardware to measure the receive signals.

To train the IO interface of memory die 132, controller 114 can generate and send a known data pattern over channel 116 to device 120. In one example, device 120 returns the data to device 110, and controller 114 can determine what errors may have occurred. Controller 114 can shmoo the signals by adjusting various voltage levels or current levels or both current and voltage levels. In general, the testing shmoos signal parameters to test the bit error rate at different parameter settings until the BER (bit error rate) is within an accepted range.

The tester typically runs a shmoo plot in the voltage domain and in the time domain to generate a passing window (PW). The passing window allows a system to determine a PASS/FAIL for a given bit stream at a given voltage and time combination for combinations corresponding to the transmitted eye.

The PW (passing window) can be defined as the receive eye plus the setup and hold time. The tester can measure the transmit data eye 142 and the passing window, allowing it to calculate the true setup and hold aperture to determine the eye received by: RX eye (R)=Passing Window (PW)+true Setup and Hold Time (tTSH). By using the same dies across multiple interfaces for calibration, a known channel/package interface can be used to determine the channel loss. The system can determine a receive eye based on the RX window and computed setup and hold times, which provides values that can be used to calibrate the system for other interfaces.

FIG. 1B is a block diagram of an example of a system that trains I/O for multiple memory dies based on a characteristic receive eye parameter for the memory dies. System 104 includes two devices coupled over a communication channel, where the receiver has multiple integrated circuit dies. System 104 represents a system with two devices that communicate over an HSIO channel. Channel 156 represents the high-speed channel.

Whereas system 102 is a single device system, system 104 is a multi-die system. In one example, system 104 is an example of a memory subsystem, with device 150 as the host/memory controller, and device 160 as the memory device (e.g., DRAM device, NAND device, or other device) having multiple memory dies. Device 160 can represent a DIMM (dual inline memory module), HBM (high bandwidth memory), or other package having multiple DRAM dies. Device 160 can represent an SSD (solid state drive) or other device having NAND memory.

Device 150 includes PHY (physical interface) 152 and device 160 includes PHY (physical interface) 162. PHY 152 and PHY 162 can be in accordance with any example above with respect to PHY 112 and PHY 122. The physical interfaces include DQ (data) signal line interfaces, CMD (command) signal line interfaces, and FB (feedback) signal line interfaces.

Device 150 includes controller 154, which represents control logic for device 150. Controller 154 includes hardware logic to control PHY 152. Controller 154 can execute firmware to manage PHY 152. Controller 154 can manage the voltage levels for the transmit signals that make up the transmit data eye. Device 160 will also have a controller to manage PHY 162, which is not specifically illustrated in system 104.

Where system 102 has interface 130 to receive a single memory die, system 104 includes multiple interfaces, illustrated as interface 180 . . . interface 182. The multiple interfaces can receive multiple components, memory die 132 . . . memory die 184. Consider an example where there are there are 10 memory dies to test. In one example, the number of dies is in a power of 2 (2, 4, 8, . . . ). The bit quality degrades further when more devices are connected to the bus. For a lightly loaded channel, as in system 102, the system can probe and determine the receive bit characteristics. However, channel 156 is more heavily loaded, and thus, probing it introduces too much noise, which prevents accurately measuring the signal characteristics.

In one example, system 102 determines setup and hold characteristics for memory die 132, which is then used in system 104. The setup and hold characteristics for memory die 132 can be used for all the memory dies to test in system 104, relying on the statistical similarity in the same device type to characterize others. Thus, system 104 represents a test platform that can be calibrated to test the HSIO for multiple dies based on the characteristics measured for a die on the platform of system 102.

More generally, one platform is used to characterize a chip on a single chip platform, and the same chip, or multiple chips of the same type, can be tested on a multi-die package test platform. The multiple dies can be laid out on a common substrate or can be stacked vertically, such as in a multichip package (MCP). The second test platform can be calibrated based on the characteristics of the chip on the single chip platform.

Without characterizing the receive eye characteristics for memory die 132, a system could use estimated capacitance on empty die sockets or empty interfaces for the memory dies. By characterizing the receive eye on the first platform, system 104 can then benefit from knowing the characteristic parameters, enabling system 104 to compute the receive eye more accurately for a multi-die configuration.

Transmit data eye 176 represents the data eye transmitted from the DQ interfaces from PHY 152. Transmit data eye 176 has known EWt (transmit eye width) and known EHt (transmit eye height). The transmit data eye is defined by the area enclosed within the vertical limits of VUPRt (transmit upper voltage) and VLWRt (transmit lower voltage) and horizontally as complementary signals cross VREFt (transmit reference voltage). The dark lines represent averages of transmitted signals, with signals rising to VUPRt being asserted bits (a logic one) and signals going to VLWRt being de-asserted bits (a logic zero).

After transmission on channel 156, the data eye will shrink due to channel loss. The representation in system 102 is not necessarily representative of a real signal, but illustrates a smaller receive data eye 172. With device 150 as the tester, the bits it sends on the DQ bus to device 160 are clean waveforms. Regardless of what is shown in system 104, the waveform for what is measured at the waveform is not necessarily as clean as the transmit signals.

Receive data eye 172 has EWr (receive eye width) and EHr (receive eye height). The receive data eye is defined by the area enclosed within the vertical limits of VUPRr (receive upper voltage) and VLWRr (receive lower voltage) and horizontally as complementary signals cross VREFr (receive reference voltage). In one example, system 104 can start with the same transmit data eye as the other platform, and then shmoo the signals based on calibration according to memory die 132, and then determine the appropriate transmit data eye for the dies mounted in device 160.

System 104 illustrates a dashed outline of transmit data eye 176 over receive data eye 172, labeled as “transmit data eye overlay”. The diagram illustrates the difference in setup and hold times between receive data eye 172 and transmit data eye 176 as channel loss 174. While the setup and hold time differences between the transmit eye and the receive eye are illustrated as being relatively the same, in one example, the setup time is longer than the hold time. In one example, the setup time is shorter than the hold time. Channel loss 174 can be determined for the memory dies based on the characterization of receive parameters for memory die 132.

The performance of the minimum specifications is determined at the receiver. In one example, system 104 determines the channel loss for the devices under test indirectly. System 104 can then start with transmit data eye 176 at the same levels as transmit data eye 142 of system 102, and then adjust the transmit data eye for a proper passing window at the memory dies of device 160.

Thus, testing can use one calibrated platform and silicon to calibrate another platform or package with the silicon characteristics of the first platform. In one example, the second platform would only need to be calibrated once, when it is brought online.

Bench tests typically test single device, and are very accurate. With the characterizing and calibrating described, a system for volume testing can be nearly as accurate as the bench testing. Instead of the volume testing being much less accurate than bench testing, there can be very close agreement between bench testing and volume testing.

It will be understood that channel loss is frequency dependent, seeing that impedance is frequency dependent. Thus, if the transmit signal is changed, there will be a change in the frequency, which will affect what happens at the receiver. However, it will also be understood that a change in the transmitter will have a similar characteristic change at the receiver. Thus, the change in the transmitter will be balanced out with a change at the receiver. Since the passing for IO testing occurs only at the receiver, changes at the transmitter are not important, and the signal at the transmitter can be changed as needed to generate passing results at the receiver.

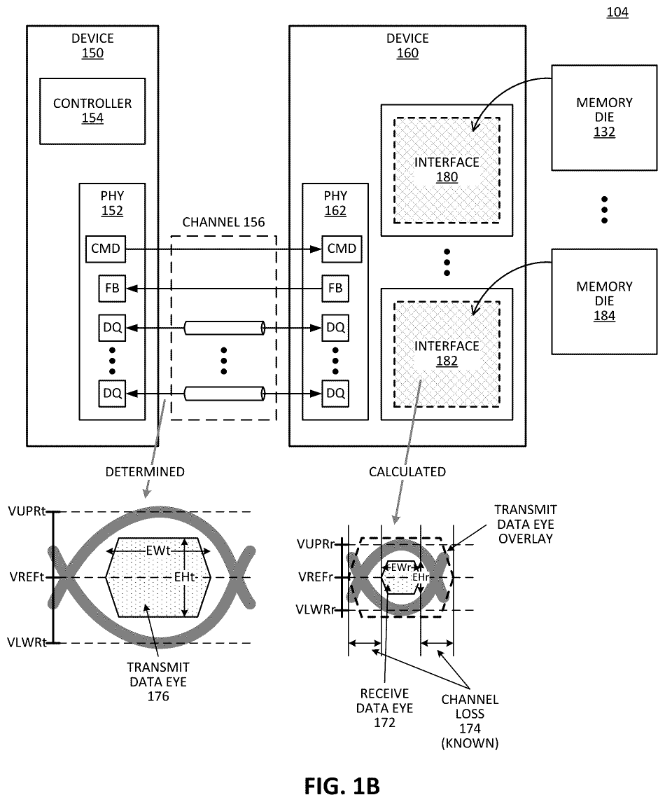

FIG. 2 is a diagrammatic example of a receive data eye in response to a transmit data eye. Diagram 200 represents an example of a transmitted eye and a received eye for a system in accordance with an example of system 102 or an example of system 104. Diagram 200 illustrates transmitted eye 210, which represents a TX data eye for a test platform, and received eye 220, which represents an RX data eye for the test platform.

Diagram 200 illustrates three equations used to determine parameters of data eyes for testing. The equations can be referred to as Equation 1 (EQN (1)), Equation 2 (EQN (2)), and Equation 3 (EQN (3)).

$$Received eye ( R ) = Transmit eye ( T ) - Channel loss ( CL ) . \qquad EQN ( 1 )$$

EQN (2): True (ttDS)=Tester Setup (tDS)−setup channel loss (CL_{S}); similarly: True (ttDH)=Tester Hold (tDSH)−hold channel loss (CL_{H}). The total channel loss is the setup channel loss plus the hold channel loss.

$$Received eye ( R ) = Passing window ( PW ) + ttDS \& ttDH . \qquad EQN ( 3 )$$

When the transmit eye is known, Equation 1 has two variables, the received eye and the channel loss. When the received eye is measured, the channel loss can be calculated from Equation 1. Equation 2 calculates the trust setup (ttDS) and the true hold (ttDH) from the channel loss and the setup and hold times determined for the tester system. Equation 3 represents the received eye as the passing window and the true setup and true hold time.

Consider a first test platform having a low-load channel, allowing the direct observation or the direct measurement of the received eye, allowing the calculation of the channel loss. Additionally, knowing the channel loss, the true setup and true hold times can be calculated for the memory die in the first test platform based on Equation 3. The true set and hold times represent values that are intrinsic to the given hardware devices. Since the values are intrinsic, they are parameters that are characteristic for the dies.

In diagram 200, transmitted eye 210 represents a data eye for a clean waveform at the transmitter side of the test system. Received eye 220 represents the data eye at the receiver side of the test system. Passing eye 222 represents the portion of the received eye that indicates the passing window for the received signals.

The time difference between the starting edge of transmitted eye 210 and the starting edge of received eye 220 appears to be the setup time, but is the incorrect tDS (data setup time). The correct setup time is ttDS (true data setup time), which is between the leading edge of passing eye 222 and the leading edge of received eye 220. Similarly, the difference between the trailing edge of received eye 220 and the trailing edge of transmitted eye 210 is the incorrect tDH (data hold time), and the correct hold time is ttDH (true data hold time), which is between the trailing edge of passing eye 222 and the trailing edge of received eye 220.

The channel loss is the difference between the apparent setup time and the true setup time, plus the difference between the apparent hold time and the true hold time. Diagram 200 illustrates channel loss 232 as the difference between incorrect tDS and ttDS, as well as the difference between incorrect tDH and ttDH. Diagram 200 illustrates setup channel loss 232 as being greater than hold channel loss 234. Diagram 200 intentionally exaggerates differences between the setup loss and the hold loss, which can be different than what is shown. The computed channel loss is a characteristic value for the hardware of the device under test (DUT). Thus, the computed channel loss can be applied to other test platforms as a characteristic parameter for the hardware. In one example, the other test platforms apply the true setup and hold times as well as the channel loss.

After measuring the received eye in one test system to compute channel loss 230 (the sum of setup channel loss (CL) 232 and hold channel loss (CL) 234), the same hardware can be put in another test system with an uncharacterized channel. The second test system can use a transmit eye size that is the same as transmitted eye 210, and apply characteristic parameters for the received eye for the hardware to the second test system. In one example, the second test system applies the true setup and hold time to compute the sum of the passing window and the ttDS and ttDH to provide an accurate approximation of the received eye. The received eye can be determined, for example, using Equation 3. With an accurate determination of the received eye, the system can determine an appropriate transmit eye for the test system based on the computed channel loss. The transmit eye determined for the test system can be used to shmoo the parameters to test the package of the DUT for the second test system.

The system can cross check the result based on Equation 1. If the new transmitted eye is known, and the received eye is determined based on the passing window plus the true setup and hold time, the channel loss can be calculated and checked against the channel loss determined for the prior test system. Increasing the transmitted eye by an amount equal to the channel loss of the new channel should yield a new passing window approximately equivalent to the passing window of the channel in the first test system, given that ttDS and ttDH are relatively constant for the semiconductor dies.

In one example, a second test system is calibrated based on measurements from the first test system. In one example, the transmit data eye for the second test system is calibrated based on computations for the first test system. The second test system can send a transmit data eye having a size of the transmit data eye of the first test system and determine a second receive data eye at the receiver in response to the second transmit data eye. The second test system can set the transmit data eye based on the determined second receive data eye, based on measurements made in the first test system.

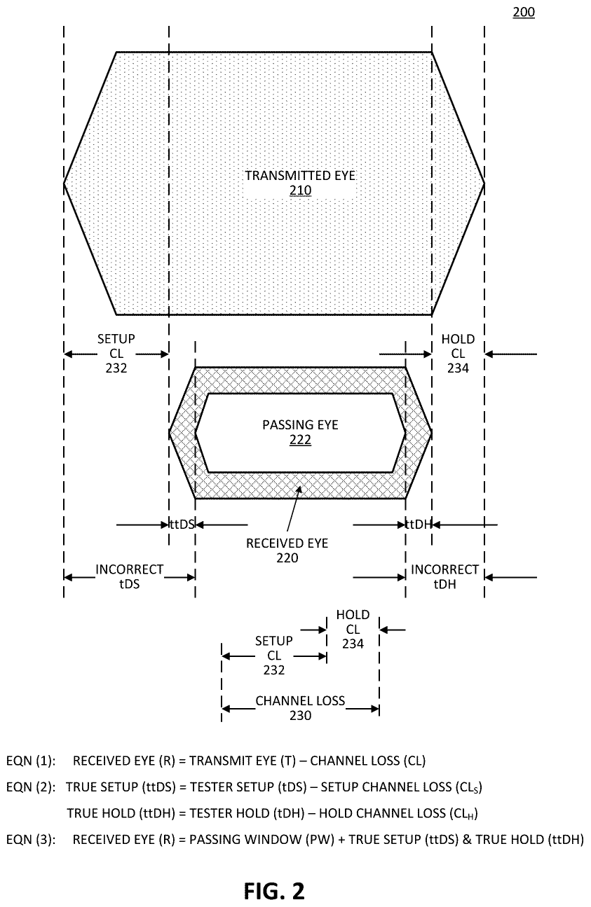

FIG. 3 is a flow diagram of an example of a process for measuring a characteristic receive eye parameter for a memory die. Process 300 represents an example of a process for characterizing channel loss.

The test system can send a test signal with a known transmit eye to a memory die or other device die under test, at 302. In one example, the system allows measurement of the receive eye, 304. In one example, the system allows measurement of the receive eye, 306. The system can determine a true setup time and a true hold time based on the measurements, at 308. The true setup and hold times can be characteristic parameters for the memory die. The system can compute a channel loss for the channel with the memory die, at 310.

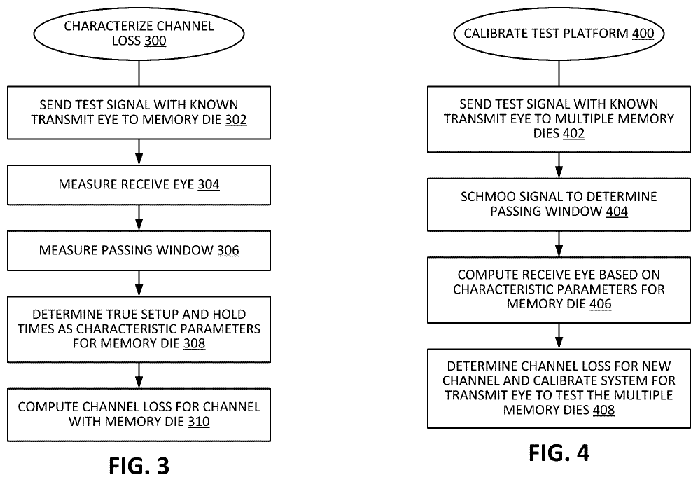

FIG. 4 is a flow diagram of an example of a process for calibrating a system based on a characteristic receive eye parameter for a memory die. Process 400 represents an example of a process for calibrating a test platform.

In one example, the test system sends a test signal with a known transmit eye to multiple memory dies, at 402. The test system can start with a transmit eye having the same size as a transmit eye used to determine memory die receive eye characteristics. With the same transmit eye size, the second system can indirectly determine its channel loss to calibrate the system for testing a different memory die package.

In one example, the system shmoos the transmit signal to determine a passing window, at 404. The system can compute a receive eye for the channel based on the characteristics parameters for the memory die, based on the passing window, at 406. In one example, the system determines a channel loss for the new channel and calibrates the system for the transmit eye to test the multiple memory dies, at 408.

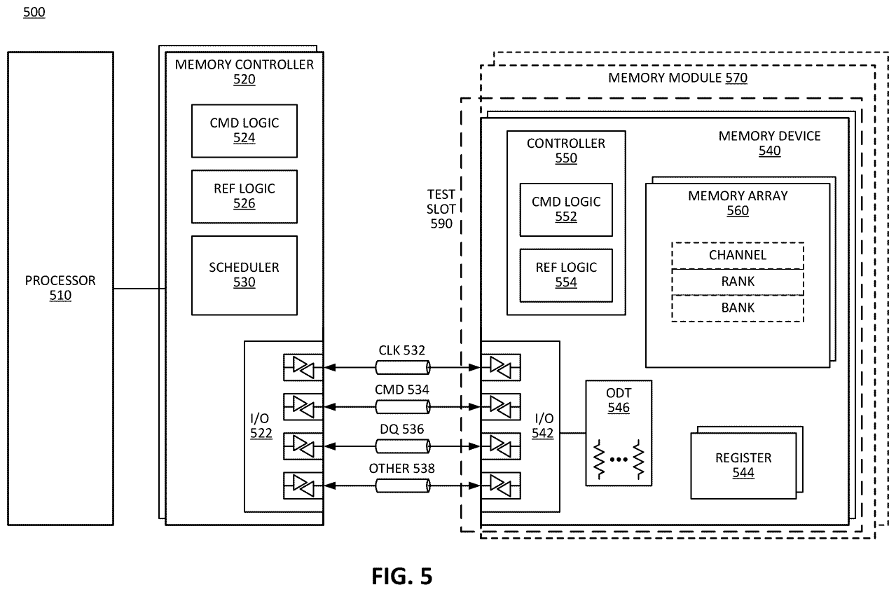

FIG. 5 is a block diagram of an example of a memory subsystem in which I/O training can be implemented. System 500 includes a processor and elements of a memory subsystem in a computing device.

System 500 represents a system with a memory subsystem in accordance with an example of system 102 or an example of system 104. In one example, system 500 represents a memory subsystem for either a first test system that measures a characteristic parameter for a device under test, or a second test system that is calibrated based on the characteristic parameter determined in the first test system. Test slot 590 represents an interface to receive a memory die to test. In one example, test slot 590 is an interface for a single memory die to be tested in the first system to measure the receive eye and compute a characteristic parameter based on the measurement. In one example, test slot 590 is an interface for multiple memory dies to be tested in the second system to calibrate based on the characteristic parameter computed in the first test system.

Processor 510 represents a processing unit of a computing platform that may execute an operating system (OS) and applications, which can collectively be referred to as the host or the user of the memory. The OS and applications execute operations that result in memory accesses. Processor 510 can include one or more separate processors. Each separate processor can include a single processing unit, a multicore processing unit, or a combination. The processing unit can be a primary processor such as a CPU (central processing unit), a peripheral processor such as a GPU (graphics processing unit), or a combination. Memory accesses may also be initiated by devices such as a network controller or hard disk controller. Such devices can be integrated with the processor in some systems or attached to the processer via a bus (e.g., PCI express), or a combination. System 500 can be implemented as an SOC (system on a chip), or be implemented with standalone components.

Reference to memory devices can apply to different memory types. Memory devices often refers to volatile memory technologies. Volatile memory is memory whose state (and therefore the data stored on it) is indeterminate if power is interrupted to the device. Nonvolatile memory refers to memory whose state is determinate even if power is interrupted to the device. Dynamic volatile memory requires refreshing the data stored in the device to maintain state. One example of dynamic volatile memory includes DRAM (dynamic random-access memory), or some variant such as synchronous DRAM (SDRAM). A memory subsystem as described herein may be compatible with a number of memory technologies, such as DDR4 (double data rate version 4, JESD79-4, originally published in September 2012 by JEDEC (Joint Electron Device Engineering Council, now the JEDEC Solid State Technology Association), LPDDR4 (low power DDR version 4, JESD209-4, originally published by JEDEC in August 2014), WIO2 (Wide I/O 2 (WideIO2), JESD229-2, originally published by JEDEC in August 2014), HBM (high bandwidth memory DRAM, JESD235A, originally published by JEDEC in November 2015), DDR5 (DDR version 5, originally published by JEDEC in July 2020), LPDDR5 (LPDDR version 5, JESD209-5, originally published by JEDEC in February 2019), HBM2 (HBM version 2, JESD235C, originally published by JEDEC in January 2020), HBM3 (HBM version 3, JESD238, originally published by JEDEC in January 2022), GDDR7 (graphics DDR version 7, in discussion), or others or combinations of memory technologies, and technologies based on derivatives or extensions of such specifications.

Memory controller 520 represents one or more memory controller circuits or devices for system 500. In one example, memory controller 520 is on the same semiconductor substrate as processor 510. Memory controller 520 represents control logic that generates memory access commands in response to the execution of operations by processor 510. Memory controller 520 accesses one or more memory devices 540. Memory devices 540 can be DRAM devices in accordance with any referred to above. In one example, memory devices 540 are organized and managed as different channels, where each channel couples to buses and signal lines that couple to multiple memory devices in parallel. Each channel is independently operable. Thus, each channel is independently accessed and controlled, and the timing, data transfer, command and address exchanges, and other operations are separate for each channel. Coupling can refer to an electrical coupling, communicative coupling, physical coupling, or a combination of these. Physical coupling can include direct contact. Electrical coupling includes an interface or interconnection that allows electrical flow between components, or allows signaling between components, or both. Communicative coupling includes connections, including wired or wireless, that enable components to exchange data.

In one example, settings for each channel are controlled by separate mode registers or other register settings. In one example, each memory controller 520 manages a separate memory channel, although system 500 can be configured to have multiple channels managed by a single controller, or to have multiple controllers on a single channel. In one example, memory controller 520 is part of host processor 510, such as logic implemented on the same die or implemented in the same package space as the processor.

Memory controller 520 includes I/O interface logic 522 to couple to a memory bus, such as a memory channel as referred to above. I/O interface logic 522 (as well as I/O interface logic 542 of memory device 540) can include pins, pads, connectors, signal lines, traces, or wires, or other hardware to connect the devices, or a combination of these. I/O interface logic 522 can include a hardware interface. As illustrated, I/O interface logic 522 includes at least drivers/transceivers for signal lines. Commonly, wires within an integrated circuit interface couple with a pad, pin, or connector to interface signal lines or traces or other wires between devices. I/O interface logic 522 can include drivers, receivers, transceivers, or termination, or other circuitry or combinations of circuitry to exchange signals on the signal lines between the devices. The exchange of signals includes at least one of transmit or receive. While shown as coupling I/O 522 from memory controller 520 to I/O 542 of memory device 540, it will be understood that in an implementation of system 500 where groups of memory devices 540 are accessed in parallel, multiple memory devices can include I/O interfaces to the same interface of memory controller 520. In an implementation of system 500 including one or more memory modules 570, I/O 542 can include interface hardware of the memory module in addition to interface hardware on the memory device itself. Other memory controllers 520 will include separate interfaces to other memory devices 540.

The bus between memory controller 520 and memory devices 540 can be implemented as multiple signal lines coupling memory controller 520 to memory devices 540. The bus may typically include at least clock (CLK) 532, command/address (CMD) 534, data (DQ) 536, and zero or more other signal lines 538. In one example, a bus or connection between memory controller 520 and memory can be referred to as a memory bus. In one example, the memory bus is a multi-drop bus. The signal lines for CMD can be referred to as a “C/A bus” (or ADD/CMD bus, or some other designation indicating the transfer of commands (C or CMD) and address (A or ADD) information) and the signal lines for write and read DQ can be referred to as a “data bus.” In one example, independent channels have different clock signals, C/A buses, data buses, and other signal lines. Thus, system 500 can be considered to have multiple “buses,” in the sense that an independent interface path can be considered a separate bus. It will be understood that in addition to the lines explicitly shown, a bus can include at least one of strobe signaling lines, alert lines, auxiliary lines, or other signal lines, or a combination. It will also be understood that serial bus technologies can be used for the connection between memory controller 520 and memory devices 540. An example of a serial bus technology is 8B10B encoding and transmission of high-speed data with embedded clock over a single differential pair of signals in each direction. In one example, CMD 534 represents signal lines shared in parallel with multiple memory devices. In one example, multiple memory devices share encoding command signal lines of CMD 534, and each has a separate chip select (CS_n) signal line to select individual memory devices.

It will be understood that in the example of system 500, the bus between memory controller 520 and memory devices 540 includes a subsidiary command bus CMD 534 and a subsidiary bus to carry the write and read data, DQ 536. In one example, the data bus can include bidirectional lines for read data and for write/command data. In another example, the subsidiary bus DQ 536 can include unidirectional write signal lines for write and data from the host to memory, and can include unidirectional lines for read data from the memory to the host. In accordance with the chosen memory technology and system design, other signals 538 may accompany a bus or sub bus, such as strobe lines DQS. Based on design of system 500, or implementation if a design supports multiple implementations, the data bus can have more or less bandwidth per memory device 540. For example, the data bus can support memory devices that have either a x4 interface, a x8 interface, a x16 interface, or other interface. The convention “xW,” where W is an integer that refers to an interface size or width of the interface of memory device 540, which represents a number of signal lines to exchange data with memory controller 520. The interface size of the memory devices is a controlling factor on how many memory devices can be used concurrently per channel in system 500 or coupled in parallel to the same signal lines. In one example, high bandwidth memory devices, wide interface devices, or stacked memory configurations, or combinations, can enable wider interfaces, such as a x128 interface, a x256 interface, a x512 interface, a x1024 interface, or other data bus interface width.

In one example, memory devices 540 and memory controller 520 exchange data over the data bus in a burst, or a sequence of consecutive data transfers. The burst corresponds to a number of transfer cycles, which is related to a bus frequency. In one example, the transfer cycle can be a whole clock cycle for transfers occurring on a same clock or strobe signal edge (e.g., on the rising edge). In one example, every clock cycle, referring to a cycle of the system clock, is separated into multiple unit intervals (UIs), where each UI is a transfer cycle. For example, double data rate transfers trigger on both edges of the clock signal (e.g., rising and falling). A burst can last for a configured number of UIs, which can be a configuration stored in a register, or triggered on the fly. For example, a sequence of eight consecutive transfer periods can be considered a burst length eight (BL8), and each memory device 540 can transfer data on each UI. Thus, a x8 memory device operating on BL8 can transfer 64 bits of data (8 data signal lines times 8 data bits transferred per line over the burst). It will be understood that this simple example is merely an illustration and is not limiting.

Memory devices 540 represent memory resources for system 500. In one example, each memory device 540 is a separate memory die. In one example, each memory device 540 can interface with multiple (e.g., 2) channels per device or die. Each memory device 540 includes I/O interface logic 542, which has a bandwidth determined by the implementation of the device (e.g., x16 or x8 or some other interface bandwidth). I/O interface logic 542 enables the memory devices to interface with memory controller 520. I/O interface logic 542 can include a hardware interface, and can be in accordance with I/O 522 of memory controller, but at the memory device end. In one example, multiple memory devices 540 are connected in parallel to the same command and data buses. In another example, multiple memory devices 540 are connected in parallel to the same command bus, and are connected to different data buses. For example, system 500 can be configured with multiple memory devices 540 coupled in parallel, with each memory device responding to a command, and accessing memory resources 560 internal to each. For a Write operation, an individual memory device 540 can write a portion of the overall data word, and for a Read operation, an individual memory device 540 can fetch a portion of the overall data word. The remaining bits of the word will be provided or received by other memory devices in parallel.

In one example, memory devices 540 are disposed directly on a motherboard or host system platform (e.g., a PCB (printed circuit board) or substrate on which processor 510 is disposed) of a computing device. In one example, memory devices 540 can be organized into memory modules 570. In one example, memory modules 570 represent dual inline memory modules (DIMMs). In one example, memory modules 570 represent other organization of multiple memory devices to share at least a portion of access or control circuitry, which can be a separate circuit, a separate device, or a separate board from the host system platform. Memory modules 570 can include multiple memory devices 540, and the memory modules can include support for multiple separate channels to the included memory devices disposed on them. In another example, memory devices 540 may be incorporated into the same package as memory controller 520, such as by techniques such as multi-chip-module (MCM), package-on-package, through-silicon via (TSV), or other techniques or combinations. Similarly, in one example, multiple memory devices 540 may be incorporated into memory modules 570, which themselves may be incorporated into the same package as memory controller 520. It will be appreciated that for these and other implementations, memory controller 520 may be part of host processor 510.

Memory devices 540 each include one or more memory arrays 560. Memory array 560 represents addressable memory locations or storage locations for data. Typically, memory array 560 is managed as rows of data, accessed via wordline (rows) and bitline (individual bits within a row) control. Memory array 560 can be organized as separate channels, ranks, and banks of memory. Channels may refer to independent control paths to storage locations within memory devices 540. Ranks may refer to common locations across multiple memory devices (e.g., same row addresses within different devices) in parallel. Banks may refer to sub-arrays of memory locations within a memory device 540. In one example, banks of memory are divided into sub-banks with at least a portion of shared circuitry (e.g., drivers, signal lines, control logic) for the sub-banks, allowing separate addressing and access. It will be understood that channels, ranks, banks, sub-banks, bank groups, or other organizations of the memory locations, and combinations of the organizations, can overlap in their application to physical resources. For example, the same physical memory locations can be accessed over a specific channel as a specific bank, which can also belong to a rank. Thus, the organization of memory resources will be understood in an inclusive, rather than exclusive, manner.

In one example, memory devices 540 include one or more registers 544. Register 544 represents one or more storage devices or storage locations that provide configuration or settings for the operation of the memory device. In one example, register 544 can provide a storage location for memory device 540 to store data for access by memory controller 520 as part of a control or management operation. In one example, register 544 includes one or more Mode Registers. In one example, register 544 includes one or more multipurpose registers. The configuration of locations within register 544 can configure memory device 540 to operate in different “modes,” where command information can trigger different operations within memory device 540 based on the mode. Additionally or in the alternative, different modes can also trigger different operation from address information or other signal lines depending on the mode. Settings of register 544 can indicate configuration for I/O settings (e.g., timing, termination or ODT (on-die termination) 546, driver configuration, or other I/O settings).

In one example, memory device 540 includes ODT 546 as part of the interface hardware associated with I/O 542. ODT 546 can be configured as mentioned above, and provide settings for impedance to be applied to the interface to specified signal lines. In one example, ODT 546 is applied to DQ signal lines. In one example, ODT 546 is applied to command signal lines. In one example, ODT 546 is applied to address signal lines. In one example, ODT 546 can be applied to any combination of the preceding. The ODT settings can be changed based on whether a memory device is a selected target of an access operation or a non-target device. ODT 546 settings can affect the timing and reflections of signaling on the terminated lines. Careful control over ODT 546 can enable higher-speed operation with improved matching of applied impedance and loading. ODT 546 can be applied to specific signal lines of I/O interface 542, 522 (for example, ODT for DQ lines or ODT for CA lines), and is not necessarily applied to all signal lines.

Memory device 540 includes controller 550, which represents control logic within the memory device to control internal operations within the memory device. For example, controller 550 decodes commands sent by memory controller 520 and generates internal operations to execute or satisfy the commands. Controller 550 can be referred to as an internal controller, and is separate from memory controller 520 of the host. Controller 550 can determine what mode is selected based on register 544, and configure the internal execution of operations for access to memory resources 560 or other operations based on the selected mode. Controller 550 generates control signals to control the routing of bits within memory device 540 to provide a proper interface for the selected mode and direct a command to the proper memory locations or addresses. Controller 550 includes command logic 552, which can decode command encoding received on command and address signal lines. Thus, command logic 552 can be or include a command decoder. With command logic 552, memory device can identify commands and generate internal operations to execute requested commands.

Referring again to memory controller 520, memory controller 520 includes command (CMD) logic 524, which represents logic or circuitry to generate commands to send to memory devices 540. The generation of the commands can refer to the command prior to scheduling, or the preparation of queued commands ready to be sent. Generally, the signaling in memory subsystems includes address information within or accompanying the command to indicate or select one or more memory locations where the memory devices should execute the command. In response to scheduling of transactions for memory device 540, memory controller 520 can issue commands via I/O 522 to cause memory device 540 to execute the commands. In one example, controller 550 of memory device 540 receives and decodes command and address information received via I/O 542 from memory controller 520. Based on the received command and address information, controller 550 can control the timing of operations of the logic and circuitry within memory device 540 to execute the commands. Controller 550 is responsible for compliance with standards or specifications within memory device 540, such as timing and signaling requirements. Memory controller 520 can implement compliance with standards or specifications by access scheduling and control.

Memory controller 520 includes scheduler 530, which represents logic or circuitry to generate and order transactions to send to memory device 540. From one perspective, the primary function of memory controller 520 could be said to schedule memory access and other transactions to memory device 540. Such scheduling can include generating the transactions themselves to implement the requests for data by processor 510 and to maintain integrity of the data (e.g., such as with commands related to refresh). Transactions can include one or more commands, and result in the transfer of commands or data or both over one or multiple timing cycles such as clock cycles or unit intervals. Transactions can be for access such as read or write or related commands or a combination, and other transactions can include memory management commands for configuration, settings, data integrity, or other commands or a combination.

Memory controller 520 typically includes logic such as scheduler 530 to allow selection and ordering of transactions to improve performance of system 500. Thus, memory controller 520 can select which of the outstanding transactions should be sent to memory device 540 in which order, which is typically achieved with logic much more complex that a simple first-in first-out algorithm. Memory controller 520 manages the transmission of the transactions to memory device 540, and manages the timing associated with the transaction. In one example, transactions have deterministic timing, which can be managed by memory controller 520 and used in determining how to schedule the transactions with scheduler 530.

In one example, memory controller 520 includes refresh (REF) logic 526. Refresh logic 526 can be used for memory resources that are volatile and need to be refreshed to retain a deterministic state. In one example, refresh logic 526 indicates a location for refresh, and a type of refresh to perform. Refresh logic 526 can trigger self-refresh within memory device 540, or execute external refreshes which can be referred to as auto refresh commands) by sending refresh commands, or a combination. In one example, controller 550 within memory device 540 includes refresh logic 554 to apply refresh within memory device 540. In one example, refresh logic 554 generates internal operations to perform refresh in accordance with an external refresh received from memory controller 520. Refresh logic 554 can determine if a refresh is directed to memory device 540, and what memory resources 560 to refresh in response to the command.

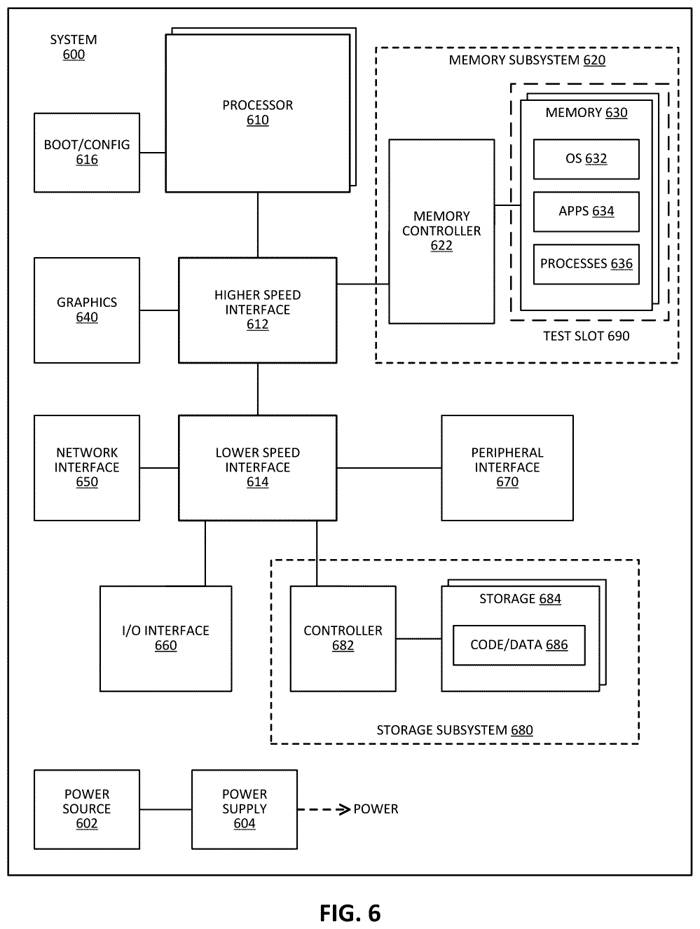

FIG. 6 is a block diagram of an example of a computing system in which I/O training can be implemented. System 600 represents a computing device in accordance with any example herein, and can be a laptop computer, a desktop computer, a tablet computer, a server, a gaming or entertainment control system, embedded computing device, or other electronic device.

System 600 represents a system with a memory subsystem in accordance with an example of system 102 or an example of system 104. In one example, system 600 represents either a first test system that measures a characteristic parameter for a device under test, or a second test system that is calibrated based on the characteristic parameter determined in the first test system. Test slot 690 represents an interface to receive a die to test. Test slot 690 is specifically illustrated around the memory as an interface for a memory die to test. It will be understood that system 600 can be implemented with an interface to test a die other than the memory dies. In one example, test slot 690 is an interface for a single die to be tested in the first system to measure the receive eye and compute a characteristic parameter based on the measurement. In one example, test slot 690 is an interface for multiple dies to be tested in the second system to calibrate based on the characteristic parameter computed in the first test system.

System 600 includes processor 610 can include any type of microprocessor, central processing unit (CPU), graphics processing unit (GPU), processing core, or other processing hardware, or a combination, to provide processing or execution of instructions for system 600. Processor 610 can be a host processor device. Processor 610 controls the overall operation of system 600, and can be or include, one or more programmable general-purpose or special-purpose microprocessors, digital signal processors (DSPs), programmable controllers, application specific integrated circuits (ASICs), programmable logic devices (PLDs), or a combination of such devices.

System 600 includes boot/config 616, which represents storage to store boot code (e.g., basic input/output system (BIOS)), configuration settings, security hardware (e.g., trusted platform module (TPM)), or other system level hardware that operates outside of a host OS. Boot/config 616 can include a nonvolatile storage device, such as read-only memory (ROM), flash memory, or other memory devices.

In one example, system 600 includes interface 612 coupled to processor 610, which can represent a higher speed interface or a high throughput interface for system components that need higher bandwidth connections, such as memory subsystem 620 or graphics interface components 640. Interface 612 represents an interface circuit, which can be a standalone component or integrated onto a processor die. Interface 612 can be integrated as a circuit onto the processor die or integrated as a component on a system on a chip. Where present, graphics interface 640 interfaces to graphics components for providing a visual display to a user of system 600. Graphics interface 640 can be a standalone component or integrated onto the processor die or system on a chip. In one example, graphics interface 640 can drive a high definition (HD) display or ultra high definition (UHD) display that provides an output to a user. In one example, the display can include a touchscreen display. In one example, graphics interface 640 generates a display based on data stored in memory 630 or based on operations executed by processor 610 or both.

Memory subsystem 620 represents the main memory of system 600, and provides storage for code to be executed by processor 610, or data values to be used in executing a routine. Memory subsystem 620 can include one or more varieties of random-access memory (RAM) such as DRAM, 3DXP (three-dimensional crosspoint), or other memory devices, or a combination of such devices. Memory 630 stores and hosts, among other things, operating system (OS) 632 to provide a software platform for execution of instructions in system 600. Additionally, applications 634 can execute on the software platform of OS 632 from memory 630. Applications 634 represent programs that have their own operational logic to perform execution of one or more functions. Processes 636 represent agents or routines that provide auxiliary functions to OS 632 or one or more applications 634 or a combination. OS 632, applications 634, and processes 636 provide software logic to provide functions for system 600. In one example, memory subsystem 620 includes memory controller 622, which is a memory controller to generate and issue commands to memory 630. It will be understood that memory controller 622 could be a physical part of processor 610 or a physical part of interface 612. For example, memory controller 622 can be an integrated memory controller, integrated onto a circuit with processor 610, such as integrated onto the processor die or a system on a chip.

While not specifically illustrated, it will be understood that system 600 can include one or more buses or bus systems between devices, such as a memory bus, a graphics bus, interface buses, or others. Buses or other signal lines can communicatively or electrically couple components together, or both communicatively and electrically couple the components. Buses can include physical communication lines, point-to-point connections, bridges, adapters, controllers, or other circuitry or a combination. Buses can include, for example, one or more of a system bus, a Peripheral Component Interconnect (PCI) bus, a HyperTransport or industry standard architecture (ISA) bus, a small computer system interface (SCSI) bus, a universal serial bus (USB), or other bus, or a combination.

In one example, system 600 includes interface 614, which can be coupled to interface 612. Interface 614 can be a lower speed interface than interface 612. In one example, interface 614 represents an interface circuit, which can include standalone components and integrated circuitry. In one example, multiple user interface components or peripheral components, or both, couple to interface 614. Network interface 650 provides system 600 the ability to communicate with remote devices (e.g., servers or other computing devices) over one or more networks. Network interface 650 can include an Ethernet adapter, wireless interconnection components, cellular network interconnection components, USB (universal serial bus), or other wired or wireless standards-based or proprietary interfaces. Network interface 650 can exchange data with a remote device, which can include sending data stored in memory or receiving data to be stored in memory.

In one example, system 600 includes one or more input/output (I/O) interface(s) 660. I/O interface 660 can include one or more interface components through which a user interacts with system 600 (e.g., audio, alphanumeric, tactile/touch, or other interfacing). Peripheral interface 670 can include any hardware interface not specifically mentioned above. Peripherals refer generally to devices that connect dependently to system 600. A dependent connection is one where system 600 provides the software platform or hardware platform or both on which operation executes, and with which a user interacts.

In one example, system 600 includes storage subsystem 680 to store data in a nonvolatile manner. In one example, in certain system implementations, at least certain components of storage 680 can overlap with components of memory subsystem 620. Storage subsystem 680 includes storage device(s) 684, which can be or include any conventional medium for storing large amounts of data in a nonvolatile manner, such as one or more magnetic, solid state, NAND, 3DXP, or optical based disks, or a combination. Storage 684 holds code or instructions and data 686 in a persistent state (i.e., the value is retained despite interruption of power to system 600). Storage 684 can be generically considered to be a “memory,” although memory 630 is typically the executing or operating memory to provide instructions to processor 610. Whereas storage 684 is nonvolatile, memory 630 can include volatile memory (i.e., the value or state of the data is indeterminate if power is interrupted to system 600). In one example, storage subsystem 680 includes controller 682 to interface with storage 684. In one example controller 682 is a physical part of interface 614 or processor 610, or can include circuits or logic in both processor 610 and interface 614.

Power source 602 provides power to the components of system 600. More specifically, power source 602 typically interfaces to one or multiple power supplies 604 in system 600 to provide power to the components of system 600. In one example, power supply 604 includes an AC to DC (alternating current to direct current) adapter to plug into a wall outlet. Such AC power can be renewable energy (e.g., solar power) power source 602. In one example, power source 602 includes a DC power source, such as an external AC to DC converter. In one example, power source 602 or power supply 604 includes wireless charging hardware to charge via proximity to a charging field. In one example, power source 602 can include an internal battery or fuel cell source.

In general with respect to the descriptions herein, in one aspect, a system for memory testing includes: an interface to receive a memory die on a second platform, the memory die having a characteristic receive eye parameter computed for a first platform based on a known first transmit data eye for the first platform and a first receive data eye measured at the memory die on the first platform in response to a first test signal on a first channel; and circuitry to test data input/output (I/O) of the memory die, including to send a second test signal on a second channel to the memory die, the second platform having a second transmit data eye calibrated based on a computed channel loss based on the characteristic receive eye parameter for the memory die.

In one example of the system, to calibrate the second transmit data eye, the circuitry is to: send the second transmit data eye having a size of the first transmit data eye; determine a second receive passing window based on the second transmit data eye; compute a channel loss for the second channel based on the determined second receive passing window and the characteristic receive eye parameter; and set the second transmit data eye based on the computed channel loss for the second channel.

In accordance with any preceding example of the system, in one example, the first platform comprises a single die test platform. In accordance with any preceding example of the system, in one example, the second platform comprises a multi-die test platform. In accordance with any preceding example of the system, in one example, the second platform comprises a dual inline memory module (DIMM). In accordance with any preceding example of the system, in one example, the second platform comprises a multichip package. In accordance with any preceding example of the system, in one example, the second platform comprises a single die test platform, where the second channel has more noise than the first channel.

In general with respect to the descriptions herein, in one aspect, a method for memory testing includes: computing a characteristic receive eye parameter for a memory die on a first platform based on a known first transmit data eye for the first platform and a first receive data eye measured at the memory die on the first platform in response to a first test signal on a first channel; calibrating a second transmit data eye of a second platform based on a computed channel loss based on the characteristic receive eye parameter for the memory die; and sending a test signal to the memory die on a second channel of the second platform with the calibrated second transmit data eye.

In one example of the method, calibrating the second transmit data eye comprises: sending the second transmit data eye having a size of the first transmit data eye; determining a second receive passing window based on the second transmit data eye; computing a channel loss for the second channel based on the determined second receive passing window and the characteristic receive eye parameter; and setting the second transmit data eye based on the computed channel loss for the second channel.

In accordance with any preceding example of the method, in one example, the first platform comprises a single die test platform. In accordance with any preceding example of the method, in one example, the second platform comprises a multi-die test platform. In accordance with any preceding example of the method, in one example, the second platform comprises a dual inline memory module (DIMM). In accordance with any preceding example of the method, in one example, the second platform comprises a multichip package. In accordance with any preceding example of the method, in one example, the second platform comprises a single die test platform, where the second channel has more noise than the first channel.

In general with respect to the descriptions herein, in one aspect, a computer readable storage medium includes: computing a characteristic receive eye parameter for a memory die on a first platform based on a known first transmit data eye for the first platform and a first receive data eye measured at the memory die on the first platform in response to a first test signal on a first channel; calibrating a second transmit data eye of a second platform based on a computed channel loss based on the characteristic receive eye parameter for the memory die; and sending a test signal to the memory die on a second channel of the second platform with the calibrated second transmit data eye.

In one example of the computer readable storage medium, calibrating the second transmit data eye comprises: sending the second transmit data eye having a size of the first transmit data eye; determining a second receive passing window based on the second transmit data eye; computing a channel loss for the second channel based on the determined second receive passing window and the characteristic receive eye parameter; and setting the second transmit data eye based on the computed channel loss for the second channel.

In accordance with any preceding example of the computer readable storage medium, in one example, the first platform comprises a single die test platform. In accordance with any preceding example of the computer readable storage medium, in one example, the second platform comprises a multi-die test platform, or wherein the second platform comprises a single die test platform, where the second channel has more noise than the first channel. In accordance with any preceding example of the computer readable storage medium, in one example, the second platform comprises a dual inline memory module (DIMM). In accordance with any preceding example of the computer readable storage medium, in one example, the second platform comprises a multichip package.

Flow diagrams as illustrated herein provide examples of sequences of various process actions. The flow diagrams can indicate operations to be executed by a software or firmware routine, as well as physical operations. A flow diagram can illustrate an example of the implementation of states of a finite state machine (FSM), which can be implemented in hardware and/or software. Although shown in a particular sequence or order, unless otherwise specified, the order of the actions can be modified. Thus, the illustrated diagrams should be understood only as examples, and the process can be performed in a different order, and some actions can be performed in parallel. Additionally, one or more actions can be omitted; thus, not all implementations will perform all actions.

To the extent various operations or functions are described herein, they can be described or defined as software code, instructions, configuration, and/or data. The content can be directly executable (“object” or “executable” form), source code, or difference code (“delta” or “patch” code). The software content of what is described herein can be provided via an article of manufacture with the content stored thereon, or via a method of operating a communication interface to send data via the communication interface. A machine readable storage medium can cause a machine to perform the functions or operations described, and includes any mechanism that stores information in a form accessible by a machine (e.g., computing device, electronic system, etc.), such as recordable/non-recordable media (e.g., read only memory (ROM), random access memory (RAM), magnetic disk storage media, optical storage media, flash memory devices, etc.). A communication interface includes any mechanism that interfaces to any of a hardwired, wireless, optical, etc., medium to communicate to another device, such as a memory bus interface, a processor bus interface, an Internet connection, a disk controller, etc. The communication interface can be configured by providing configuration parameters and/or sending signals to prepare the communication interface to provide a data signal describing the software content. The communication interface can be accessed via one or more commands or signals sent to the communication interface.

Various components described herein can be a means for performing the operations or functions described. Each component described herein includes software, hardware, or a combination of these. The components can be implemented as software modules, hardware modules, special-purpose hardware (e.g., application specific hardware, application specific integrated circuits (ASICs), digital signal processors (DSPs), etc.), embedded controllers, hardwired circuitry, etc.

Besides what is described herein, various modifications can be made to what is disclosed and implementations of the invention without departing from their scope. Therefore, the illustrations and examples herein should be construed in an illustrative, and not a restrictive sense. The scope of the invention should be measured solely by reference to the claims that follow.

What is claimed is:

1. A system for memory testing, comprising:
an interface to receive a memory die on a second platform, the memory die having a characteristic receive eye parameter computed for a first platform based on a known first transmit data eye for the first platform and a first receive data eye measured at the memory die on the first platform in response to a first test signal on a first channel; and
circuitry to test data input/output (I/O) of the memory die, including to send a second test signal on a second channel to the memory die, the second platform having a second transmit data eye calibrated based on a computed channel loss based on the characteristic receive eye parameter for the memory die.

2. The system of claim 1, wherein, to calibrate the second transmit data eye, the circuitry is to:
send the second transmit data eye having a size of the first transmit data eye;
determine a second receive passing window based on the second transmit data eye;
compute a channel loss for the second channel based on the determined second receive passing window and the characteristic receive eye parameter; and
set the second transmit data eye based on the computed channel loss for the second channel.

3. The system of claim 1, wherein the first platform comprises a single die test platform.

4. The system of claim 1, wherein the second platform comprises a multi-die test platform.

5. The system of claim 4, wherein the second platform comprises a dual inline memory module (DIMM).

6. The system of claim 4, wherein the second platform comprises a multichip package.

7. The system of claim 1, wherein the second platform comprises a single die test platform, where the second channel has more noise than the first channel.

8. A method for memory testing, comprising:
computing a characteristic receive eye parameter for a memory die on a first platform based on a known first transmit data eye for the first platform and a first receive data eye measured at the memory die on the first platform in response to a first test signal on a first channel;
calibrating a second transmit data eye of a second platform based on a computed channel loss based on the characteristic receive eye parameter for the memory die; and
sending a test signal to the memory die on a second channel of the second platform with the calibrated second transmit data eye.

9. The method of claim 8, wherein calibrating the second transmit data eye comprises:
sending the second transmit data eye having a size of the first transmit data eye;
determining a second receive passing window based on the second transmit data eye;
computing a channel loss for the second channel based on the determined second receive passing window and the characteristic receive eye parameter; and
setting the second transmit data eye based on the computed channel loss for the second channel.

10. The method of claim 8, wherein the first platform comprises a single die test platform.

11. The method of claim 8, wherein the second platform comprises a multi-die test platform.

12. The method of claim 11, wherein the second platform comprises a dual inline memory module (DIMM).

13. The method of claim 11, wherein the second platform comprises a multichip package.

14. The method of claim 8, wherein the second platform comprises a single die test platform, where the second channel has more noise than the first channel.

15. A computer readable storage medium having stored thereon instructions, which when executed causes a machine to perform operations to execute a method including:
computing a characteristic receive eye parameter for a memory die on a first platform based on a known first transmit data eye for the first platform and a first receive data eye measured at the memory die on the first platform in response to a first test signal on a first channel;
calibrating a second transmit data eye of a second platform based on a computed channel loss based on the characteristic receive eye parameter for the memory die; and
sending a test signal to the memory die on a second channel of the second platform with the calibrated second transmit data eye.

16. The computer readable storage medium of claim 15, wherein calibrating the second transmit data eye comprises:
sending the second transmit data eye having a size of the first transmit data eye;
determining a second receive passing window based on the second transmit data eye;
computing a channel loss for the second channel based on the determined second receive passing window and the characteristic receive eye parameter; and
setting the second transmit data eye based on the computed channel loss for the second channel.

17. The computer readable storage medium of claim 15, wherein the first platform comprises a single die test platform.

18. The computer readable storage medium of claim 15, wherein the second platform comprises a multi-die test platform, or wherein the second platform comprises a single die test platform, where the second channel has more noise than the first channel.

19. The computer readable storage medium of claim 18, wherein the second platform comprises a dual inline memory module (DIMM).

20. The computer readable storage medium of claim 18, wherein the second platform comprises a multichip package.
